(19) United States
(12) Patent Application Publication
(10) Pub. No.: US 2018/0009664 A1
(43) Pub. Date: Jan. 11, 2018

(54) METHOD FOR SYNTHESIZING CARBON MATERIALS FROM CARBON AGGLOMERATES CONTAINING CARBINE/CARBYNOID CHAINS

(71) Applicants: Ecole Polytechnique, Palaiseau (FR); Centre National De La Recherche Scientifique, Paris (FR)

(72) Inventor: Costel-Sorin Cojocaru, Palaiseau (FR)

(21) Appl. No.: 15/540,754

(22) PCT Filed: Dec. 23, 2015
(86) PCT No.: PCT/IB2015/059934

§ 371 Date: Jun. 29, 2017

(30) Foreign Application Priority Data
Jan. 5, 2015 (FR) 1550032

(51) Int. Cl. C09D 1/00; H01L 51/00; B82Y 40/00; H01L 29/16; B82Y 30/00

(52) U.S. Cl. CPC C01B 32/05; C09D 1/00; C01B 32/184; C01B 32/154; C01B 32/26; C01B 32/205; H01L 29/1602; B82Y 30/00; B82Y 40/00; H01L 29/1606; H01L 51/0046; Y10S 977/734; Y10S 977/842; Y10S 977/932

(57) ABSTRACT

Provided is a method for synthesizing carbon agglomerates containing metastable carbyne/carbynoid chains; a method for synthesizing carbon or carbon compound allotropes from the agglomerates containing metastable carbyne/carbynoid chains; and the uses of the methods. The method for synthesizing carbon agglomerates containing metastable carbyne/carbynoid chains includes the following steps: a) forming carbon vapor precursors, containing carbine/carbynoid chains, by decomposing a carbon gas selected from among CH₄, C₂H₂, C₂H₄, gaseous toluene, and benzene in the form of vapors at a temperature T such that 1 500° C.<T≦3 000° C.; and b) condensing the carbon vapor precursors, obtained in Step a), on the surface of a substrate, the temperature Ts of which is less than the temperature T. The invention is particularly of use in the field of electronics.

The invention relates to a process for the synthesis of carbon agglomerates containing metastable carbyne/carbynoid chains.

It also relates to a process for the synthesis of carbon allotropes or carbon compounds from these agglomerates containing metastable carbyne/carbynoid chains.

It also relates to the uses of these processes.

Carbyne is an allotrope of carbon which consists of a linear chain of carbon of sp hybridization with the chemical structure (—C≡C—)ₙ or (═C═C═)ₙ, as a repeat unit.

Due to the alternating presence of single and triple bonds, this would thus be the final member of the family with polyynes, while having a cumulene electronic structure when formed by sequential double bonds along the chain.

A carbynoid is a chain of carbynes of variable length, the ends of which are stabilized by various functional groups, such as, for example, metals or organometallic complexes or compounds based on carbon having a different hybridization, such as, for example, a nanographene crystal.

A polyyne is a carbon-based compound with alternating single and triple bonds, that is to say (—C≡C—)ₙ with n>1.

The simplest example of polyyne is diacetylene or buta-1,3-diyne: H—C≡C—C≡C—H.

A (poly)cumulene is a carbon-based compound having three or more consecutive cumulative double bonds. One member of these cumulene compounds is butatriene (also known simply as cumulene), H₂C═C═C═CH₂.

A graphyne or graphdiyne is an allotrope of carbon with a structure as fleet sheets, with a thickness of one atom, of carbon atoms having both sp and sp² bonds arranged in a crystal lattice. It can be seen as a lattice of benzene rings connected by acetylene chains or longer linear acetylenic chains with carbyne bonds.

According to the content of acetylene (acetylenic) groups, graphyne can be regarded as having a mixed spⁿ hybridization with 1<n<2, different from the hybridization of graphene (pure sp²) and diamond (pure sp³).

The combination of atoms of a carbon of sp², sp³ and sp hybridization can give rise to a large number of allotropic phases and forms of carbon.

To date, only carbon solids based on entirely sp³ hybridization (diamond) and entirely sp² hybridization (graphite, fullerene, carbon nanotubes and graphene) are well known and characterized.

There are certainly a large number of other possible transitional forms of carbon in which the bonds with sp, sp² and sp³ hybridization coexist in the same solid, always consisting overall of only carbon atoms (such as, for example, in certain forms of amorphous carbon, of carbon black, of glassy carbon, of coke and of soot, and the like).

The solids based on sp hybridization, which appear to be the most difficult members to achieve of the different families of allotropes of carbon, have been the subject of intense experimental efforts for the last three to four decades.

These solids are supposed to be abundant in interstellar dust clouds, where hydrogen is rare.

The existence of linear chains of carbon atoms bonded by alternating single and triple bonds (polyyne) or double bonds (polycumulene) has been demonstrated in interstellar molecular clouds and might be artificially produced by different chemical routes, in which case these linear carbon chains will be stabilized with different molecular complexes at the end of the chains.

However, to date, to the knowledge of the inventors, the effective large-scale production of carbyne or carbynoid chains (radicals) or their use as blocks of elementary molecular constructions for the synthesis of other allotropic phases and forms of carbon has never been obtained.

Nevertheless, carbyne chains are regarded as the strongest known material. The tensile strength (the ability to withstand drawing) of carbynes surpasses that of any other known material and is twice that of graphene.

It has twice the tensile stiffness of graphene and carbon nanotubes and virtually three times that of diamond.

When it is equipped with molecular handles at its chain ends, it can also be twisted to alter its band gap.

Drawing a carbyne by as little as 10% alters its electronic band gap significantly from 3.2 to 4.4 eV.

When twisted by 90°, a carbyne then becomes a magnetic semiconductor.

The assemblages of unsaturated chains of sp carbon exhibit a very high reactivity and a tendency to undergo a chain to chain crosslinking reaction bringing about change toward the sp² phase or, under certain conditions, toward the sp³ phase, which generated great skepticism with regard to the possibility of assembling chains of sp carbon to form solids made of pure carbon.

In contrast to their noteworthy physical properties, polyyne or polycumulene chains are very reactive and thus unstable: exposure to oxygen and/or to water can completely destroy these entities. However, they can also react to exposure to light or to charged particles.

The isolated carbon chains could thus only be studied in the gas phase or by means of matrix isolation spectroscopy at very low temperature.

To date, the synthetic routes generally accepted for the generation of sp chains are based either on a modification at high pressure and high temperature of carbon-based solids (carbon solids) or on chemical strategies targeted at the removal of the substituents of a linear organic molecule in order to terminate the naked linear carbon backbone.

Such “chemical” approaches include the catalytic dehydropolymerization of acetylene, the dehydrohalogenation of chlorinated polyacetylene, a coupling reaction, promoted by the air, of copper acetylide, the electrochemical reductive carbonization of poly(tetrafluoroethylene), and the like.

However, these methods generally produce carbon chains somewhat “separated” or “isolated/protected” by a great variety of reaction by-products which are used to prevent crosslinking reactions between the adjacent carbynoid chains and their decomposition.

Some researchers have reported the possibility of producing an amorphous carbon solid which contains significant amounts of carbyne or structures analogous to carbyne by means of supersonic carbon cluster beam deposition (SCBD) at ambient temperature and in an ultrahigh vacuum environment.

They have observed that such structures of linear carbon having sp hybridization are very unstable under vacuum or during exposure to oxygen: the carbon structure rapidly deteriorates and changes to form a common sp² amorphous phase carbon form, mainly.

It can thus be assumed that carbynoid and carbyne linear sp hybridization carbon aggregates are metastable structures, that is to say that they are thermodynamically unstable but occurring, however, in a state which corresponds to a local energy minimum and thus appear as kinetically stable due to their very slow reaction rate in the absence of external stimuli.

These compounds containing carbyne and/or carbynoid chains are thus very difficult to demonstrate nondestructively.

This is because high-energy electron analytical techniques (transmission electron microscopy (TEM), scanning electron microscopy (SEM)) will very probably unfortunately destroy such a material when the observation process is carried out.

Optical spectroscopy and in particular Raman spectroscopy (at low optical power densities) or low-energy electron diffraction/spectroscopy are probably the most appropriate methods.

Thus, it appears from the above that the scientific and technical challenges related to obtaining carbon compounds (carbon-based compounds) containing carbynes and/or carbynoids (hereinafter known as carbynes/carbynoids) are very important in numerous fields. They can make possible synthesis of carbon materials, such as carbon nanomaterials, graphene, graphine, graphdiyne, nanotubes, nanorubans, and the like.

They can also make it possible to synthesize novel pharmaceutical molecules based on carbon-carbon double and triple bonds; they might also make possible the synthesis of novel semiconducting materials, some having Dirac points (very high mobility of the carriers, and the like).

Thus, it is an aim of the invention to provide a process for the synthesis of carbon agglomerates and in particular the deposition in the form of layers or of films of such agglomerates:
i) having a controllable structure (sp, sp² or sp³ hybridization or mixtures of these phases, for example graphene, graphyne, graphdiyne, nanotubes, nanorubans, nanodiamond, and the like),
ii) directly on the final substrate/support,
iii) in a manner in accordance with the surface of the substrate/support,
iv) at low temperature (starting from ambient temperature), and
v) without constraints with regard to the nature of the substrate/support (for example no catalyst).

This method makes possible/facilitates:
vi) the controlled doping of the films obtained and
vii) can be carried out on a large scale or at least it is compatible with large-scale processing techniques (for example roll-to-roll).

To this end, the invention provides a process for the synthesis of carbon agglomerates containing metastable carbyne/carbynoid chains, characterized in that it comprises the following stages:
a) formation of carbon vapor precursors containing carbyne/carbynoid chains by decomposition of a carbon gas at a temperature T such that 1500° C.<T≦3000° C., and
b) condensation of the vapor precursors obtained in stage a) on the surface of a substrate, the temperature Ts of which is less than the temperature T.

In a first embodiment of this process, stage a) is a stage of forced (locally confined) passage of the carbon gas through at least one metal filament heated to the temperature T in a chemical vapor deposition (CVD) chamber.

In this case, the filament is made of a material preferably chosen from tungsten, tantanlum, molybdenum and rhenium.

In a second embodiment of this process, stage a) is a stage of localized heating by laser irradiation of the carbon gas in a CVD chamber.

In this second embodiment, the laser is preferably an infrared CO₂ laser or an excimer (UV) laser.

In all the embodiments of this process, the carbon gas is preferably chosen from CH₄, C₂H₂, C₂H₄, gaseous toluene and gaseous benzene.

Also in all the embodiments of this process, a carrier and/or diluent gas can be injected at the same time as the carbon gas.

This carrier and/or diluent gas can be argon, helium or neon.

In this case, the carbon gas can be introduced by a first orifice and the carrier and/or diluent gas introduced separately by another orifice or else the carrier and/or diluent gas is injected by the same injection orifice as the carbon gas.

The introduction of such a carrier and/or diluent gas makes it possible in particular to obtain a condensation, and/or a formation, and/or a deposition which is more homogeneous of the carbon agglomerates.

The amount by weight and volume of condensed agglomerates per unit of time can thus be varied, which is advantageous when these agglomerates are used, from their formation, to form other carbon compounds: the kinetics necessary for the reaction for formation of the desired carbon compound can thus be observed.

Also, this process can comprise, furthermore, before stage a), a stage a1) of pretreatment of the surface of the substrate on which the carbon agglomerates containing carbyne/carbynoid chains will be condensed.

This stage a1) can be a stage of pretreatment of this surface with radical hydrogen generated in situ by decomposition of H₂.

It can also be a stage of deposition on this surface of the substrate of a layer of amorphous aluminum.

Furthermore, in another embodiment of this process, at least the surface of the substrate is made of fused silica.

Still in another embodiment of this process, the surface of the substrate can be treated for the purpose of modifying its surface tension properties.

Preferably, for this purpose, the surface is functionalized with silane groups in order to modify its wettability, in particular with regard to carbon.

The invention also provides a process for the synthesis of carbon materials, characterized in that it comprises a stage A) of synthesis, by the process according to the invention described above, of carbon agglomerates comprising metastable carbyne/carbynoid chains, followed by a stage B) of transformation of the agglomerates obtained in stage A) into the desired carbon material.

In an advantageous embodiment of this process, stage B) is carried out simultaneously with the condensation stage b) of stage A) and in the same CVD chamber.

However, in another advantageous embodiment of this process, stage B) is carried out after the stage of condensation b) of stage A), optionally in a separate chamber.

Stage B) can be a stage carried out by the use of a source of photons, of electrons or of ions, focused in order to induce a local transformation of the stream of agglomerates obtained in stage A), during their deposition on the surface of the substrate, in order to manufacture, in localized fashion, the desired carbon material.

In other words, stage B) is carried out by irradiation of the agglomerates obtained in stage A), as they are deposited on the surface of the substrate, with a source of photons, of electrons or of ions, whereby a localized transformation of the agglomerates into the desired carbon material is obtained.

Stage B) can also be a stage of heating the agglomerates containing carbyne/carbynoid chains obtained in stage b) of stage A) to the temperature necessary in order to obtain the transformation of these agglomerates into the desired material.

Stage B) can also be a stage of irradiation under light, preferably UV radiation, of the agglomerates containing carbyne/carbynoid chains obtained in stage b) of stage A).

The process of the synthesis of carbon materials according to the invention can also comprise, in addition, the injection, into the CVD chamber, of a gas containing a doping element.

This gas containing a doping element can be a gas containing nitrogen, boron, phosphorus and/or fluorine, this doping element to be introduced into the carbon compound to be formed.

The gas containing a doping element can be injected by the same orifice as the starting carbon gas or by a separate orifice.

This process can also comprise, in addition, the injection of hydrogen into the CVD chamber. Hydrogen is injected in particular when it is desired to produce hydrogen radicals which will react with the carbynes/carbynoids to form the desired carbon compounds.

In this case, that is to say when it is desired to produce hydrogen radicals, the hydrogen will be injected by the same orifice as the carbon gas, in order to be decomposed therein at the same time.

However, the hydrogen can also be introduced by a separate orifice.

It will be understood that, in the process of the synthesis of carbon agglomerates containing carbyne/carbynoid chains, as in the process for the synthesis of carbon compounds according to the invention, when the carrier gas or the gas containing a doping element, or the hydrogen, respectively, is introduced by a separate orifice from that by which the starting carbon gas is introduced, it will be possible to heat this gas to a temperature different from that necessary in order to decompose the carbon gas injected in the other orifice.

This gives great flexibility for the formation of different compounds.

The invention further provides for the use of the carbon agglomerates containing metastable carbyne/carbynoid chains obtained by the process according to the invention for the synthesis of chemical molecules containing polyene and/or polycyclic chains or for the formation of conforming coatings composed solely of carbon or for the synthesis of graphenes, graphites, nanodiamonds or fullerenes.

The invention also provides for the use of the carbon agglomerates containing metastable carbyne/carbynoid chains obtained by the process according to the invention as semiconducting materials.

This is because the carbynes/carbynoids and also the materials containing these types of compounds can be semiconducting in themselves.

Processes of the irradiation type can further modify the properties of these materials by transforming them into materials with other gap values, indeed even into semimetals.

The carbon agglomerates containing metastable carbyne/carbynoid chains obtained by the process according to the invention can also be used for the manufacture of components of electronic devices or for the storage of energy.

A better understanding of the invention will be obtained and other details, characteristics and advantages of the latter will become more clearly apparent on reading the explanatory description which follows and which is made with reference to the figures, in which:

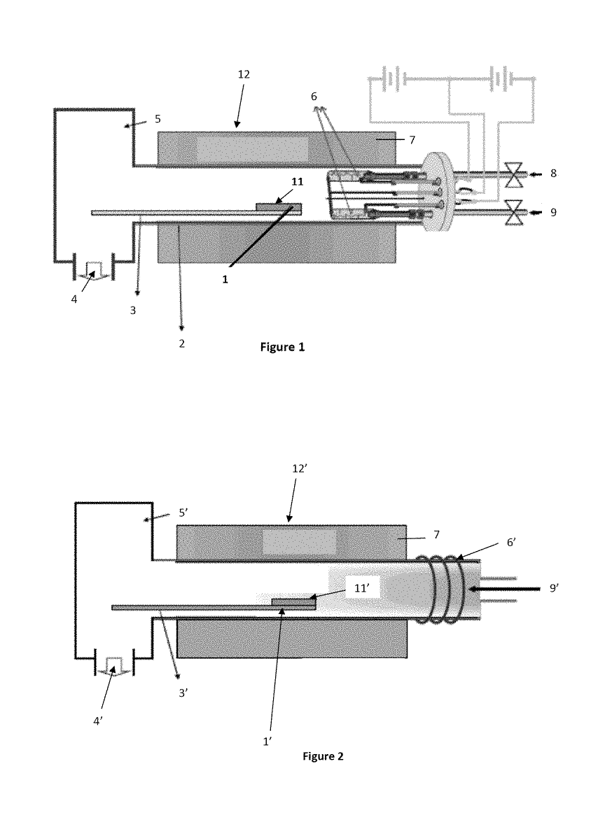

FIG. 1 diagrammatically represents a first example of a device for carrying out the processes of the invention, this device comprising two separate orifices for the separate injection of a carbon gas and of a carrier and/or diluent gas and in which the gases are heated by two hot filaments,

FIG. 2 represents a second example of a device for carrying out the processes of the invention, this device comprising just one inlet orifice for the injection of a carbon gas and optionally and simultaneously of a carrier and/or diluent gas, the gas(es) being heated by just one hot filament,

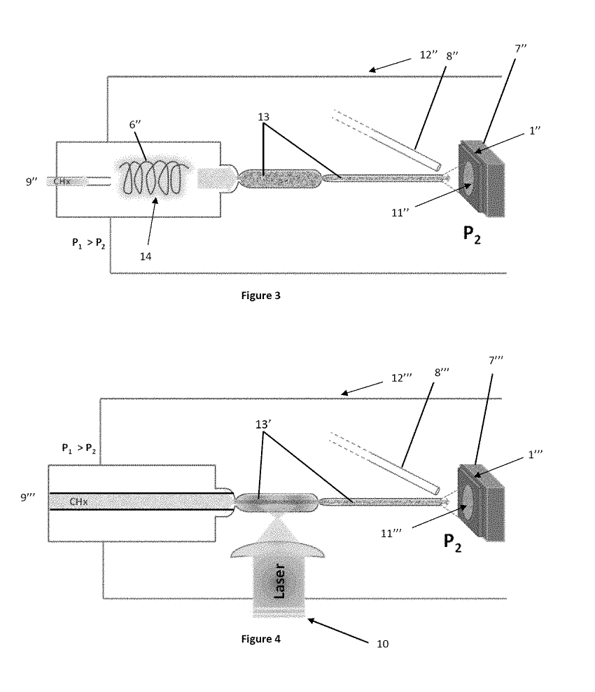

FIG. 3 represents a third device for carrying out the processes of the invention, this device comprising just one inlet orifice for a carbon gas and optionally for a carrier and/or diluent gas, the heating of this/these gas(es) being obtained by a filament and in which Laval nozzles are placed at the outlet of the region for heating by the filament in order to accelerate the gas flow,

FIG. 4 represents a fourth device for carrying out the processes of the invention, in which the heating of carbon gas is obtained by laser irradiation, this device comprising just one inlet orifice for a carbon gas and optionally for a carrier and/or diluent gas, and in which Laval nozzles are placed at the outlet of the heating region in order to accelerate the gas flow,

FIG. 5 represents the Raman spectrum of carbon agglomerates (clusters) containing metastable carbyne/carbynoid chains according to the invention and obtained by the process of the invention and by decomposition of CH₄ at 2100° C. and condensation of the decomposed gas on a glass substrate maintained at a temperature of 500° C.,

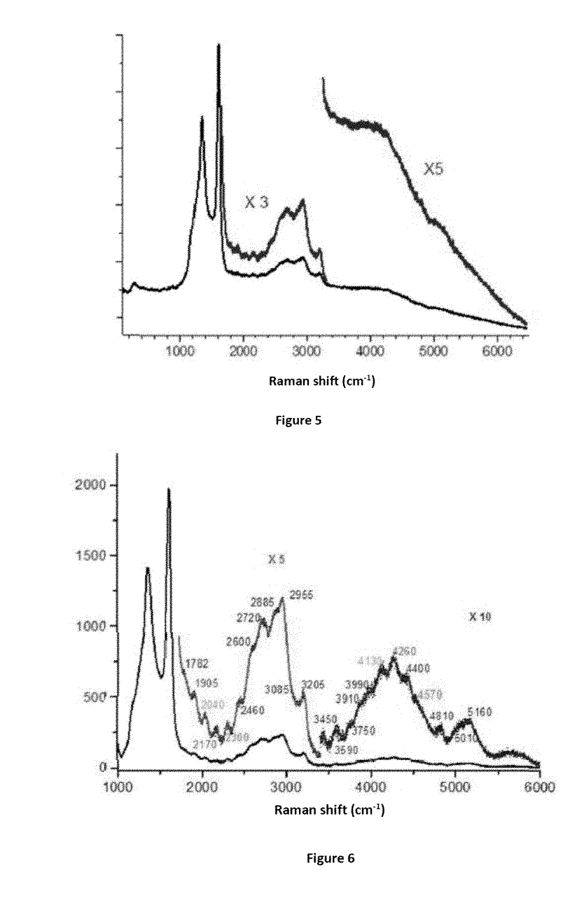

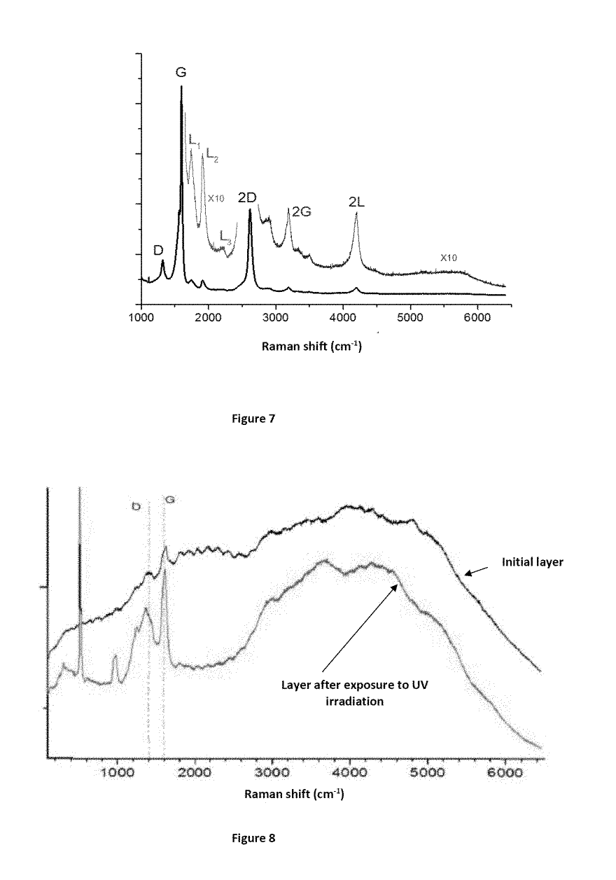

FIG. 6 represents the Raman spectrum of carbon clusters according to the invention and obtained by the synthesis process of the invention, containing metastable carbyne/carbynoid chains by decomposition of CH₄ at 2250° C. and condensation of the decomposed gas on an Al₂O₃/SiO₂/Si substrate maintained at a temperature of 450° C.,

FIG. 7 represents the Raman spectrum of a graphene layer obtained by the process for the synthesis of carbon materials according to the invention,

FIG. 8 represents the Raman spectrum of a graphite layer obtained by the process according to the invention,

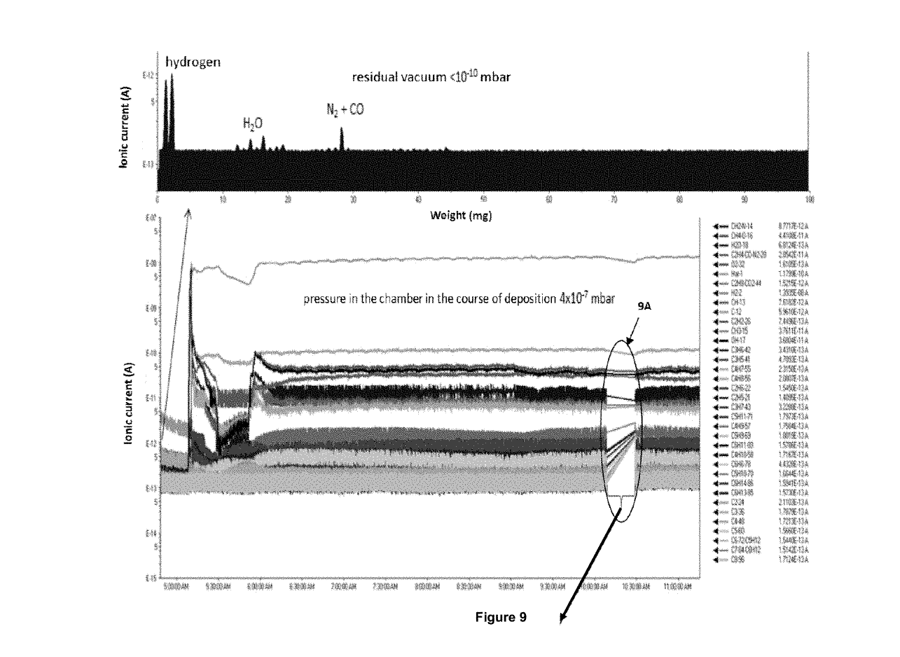

FIG. 9 represents real-time monitoring of the residual pressure, measured by mass spectroscopy, in an ultrahigh vacuum chamber before and during the implementation of the process for the formation of agglomerates according to the invention employed, carried out with the device shown in FIG. 3,

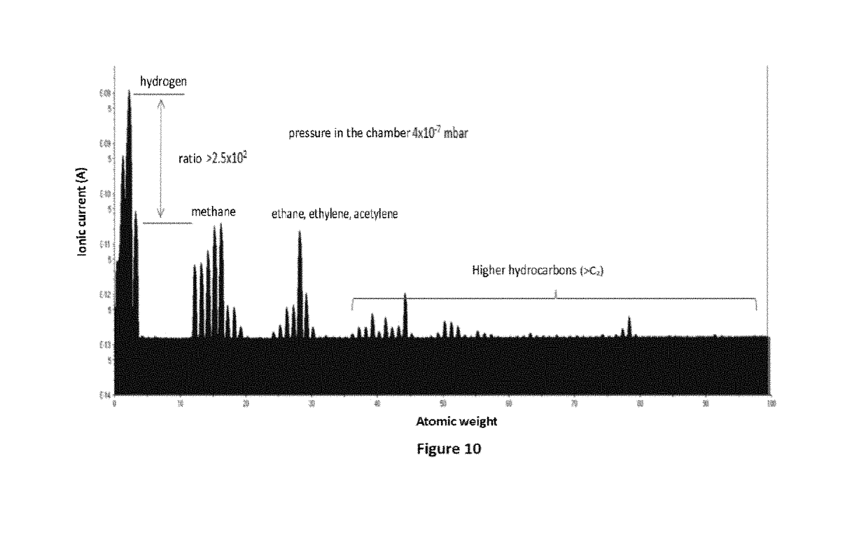

FIG. 10 shows a complete scanning from 1 to 100 amu (atomic masses) of the residual compounds present in an UHV chamber during the implementation of the process for the formation of agglomerates of the invention, at the pressures of the region denoted 9A in FIG. 9,

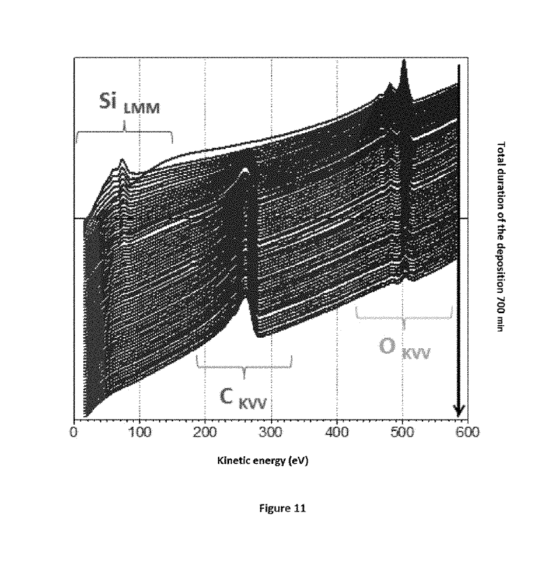

FIG. 11 represents the Auger spectrum of the layer of agglomerates containing metastable carbyne/carbynoid chains obtained by the implementation of the process for formation of agglomerates of the invention, in an ultrahigh vacuum chamber in the device shown in FIG. 3 with in situ and real-time monitoring over a period of 700 minutes,

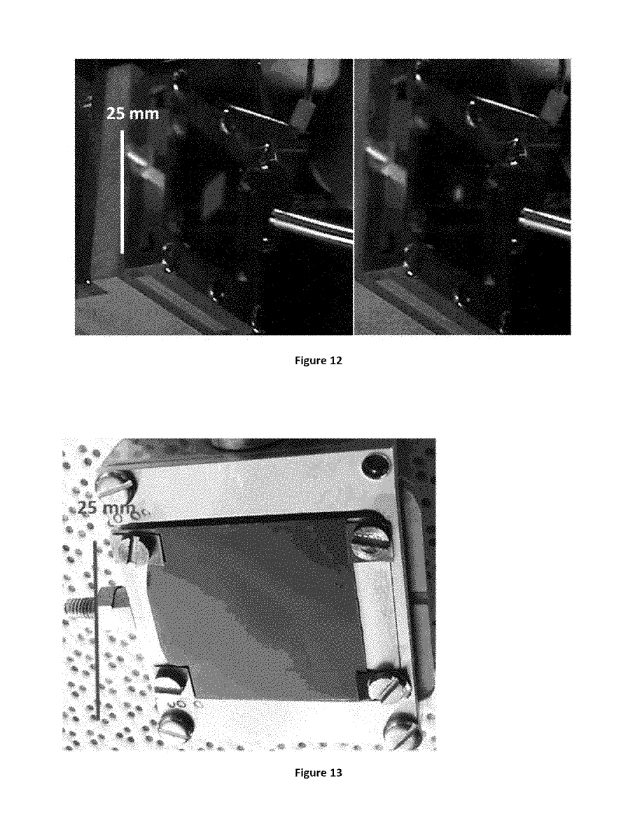

FIG. 12 is a photograph taken during the stage of localized deposition of a thin carbon layer, in an ultrahigh vacuum chamber, using the device shown in FIG. 3 and with a local transformation, in situ, at ambient temperature, of the agglomerates containing metastable carbyne/carbynoid chains using a focused beam of electrons (right-hand photograph) or in scanning mode (left-hand photograph). This same beam of electrons, of variable energy and intensity, can be used to characterize the layer formed during deposition, for example in imaging (SEM or STEM) mode or else by Auger or electron energy loss spectroscopy. The spots of fluorescence of the substrate (Si covered with a layer of thermal silica) under the effect of the irradiation by the beam of electrons are noted on these images,

FIG. 13 is an optical photograph of the layer deposited locally using the device shown in FIG. 3 and with a local transformation, in situ, of the agglomerates containing metastable carbyne/carbynoid chains using a beam of electrons in scanning mode. The correspondence of the scanning pattern shown in FIG. 12 (left-hand photograph) and the morphology of the thin layer deposited is noted,

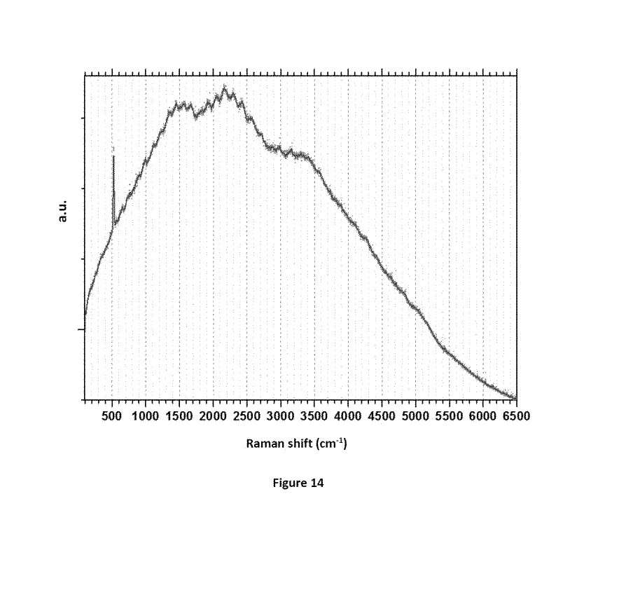

FIG. 14 shows the Raman spectra of the agglomerates containing metastable carbyne/carbynoid chains deposited (and not transformed) around the region of writing by the beam of electrons in FIGS. 12 and 13,

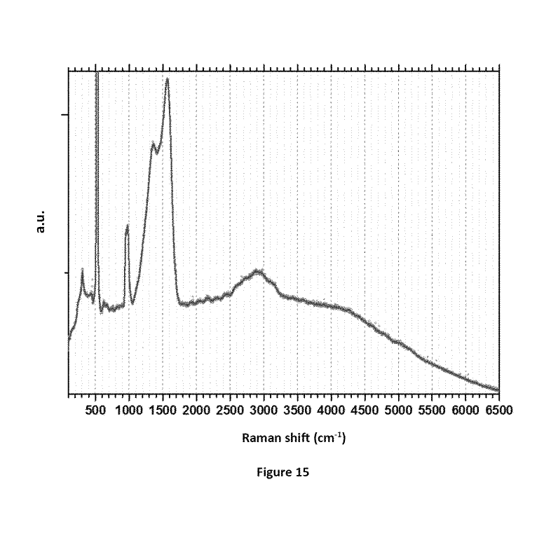

FIG. 15 shows the Raman spectrum of the thin layers shown in FIGS. 12 and 13 obtained by a local transformation, in situ, at ambient temperature, of the agglomerates containing metastable carbyne/carbynoid chains using a beam of electrons which is focused or in scanning mode,

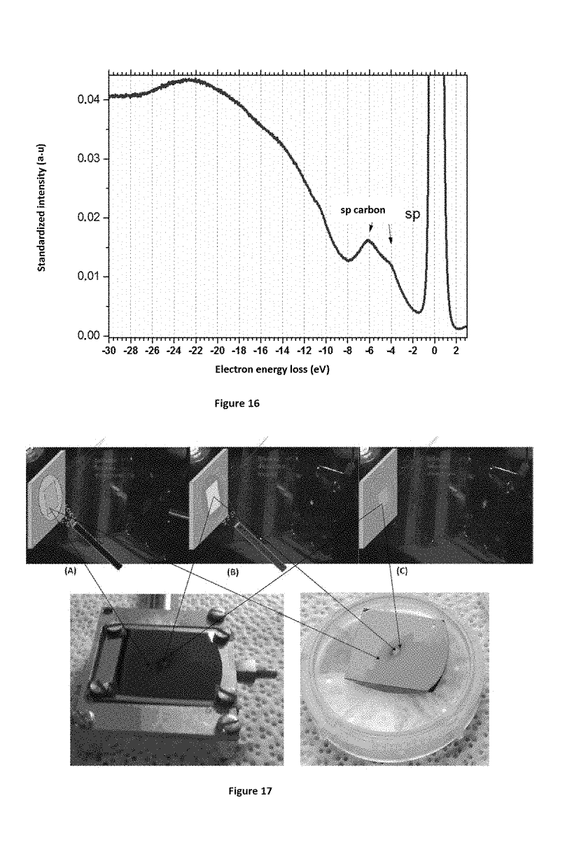

FIG. 16 shows the energy loss spectrum of the slow electrons during the deposition of a graphite layer carried out in example 5,

FIG. 17 is an illustration of the use of the local transformation, in situ, at ambient temperature, of agglomerates containing metastable carbyne/carbynoid chains using a beam of electrons according to the three basic processes in the microelectronics industry: region (A) localized deposition of a material (in this case having controllable and modifiable properties) using the metastable carbyne/carbynoid chains generated by the device shown in FIG. 3; region (B) local destruction/removal of this material using the beam of electrons in the presence of oxygen (pressure 10⁻⁶ mbar) without affecting the material in the neighboring region not exposed to the beam of electrons; and region (C) transformation of a portion of the material deposited in region (A) under the effect of exposure to a higher dose of the beam of electrons,

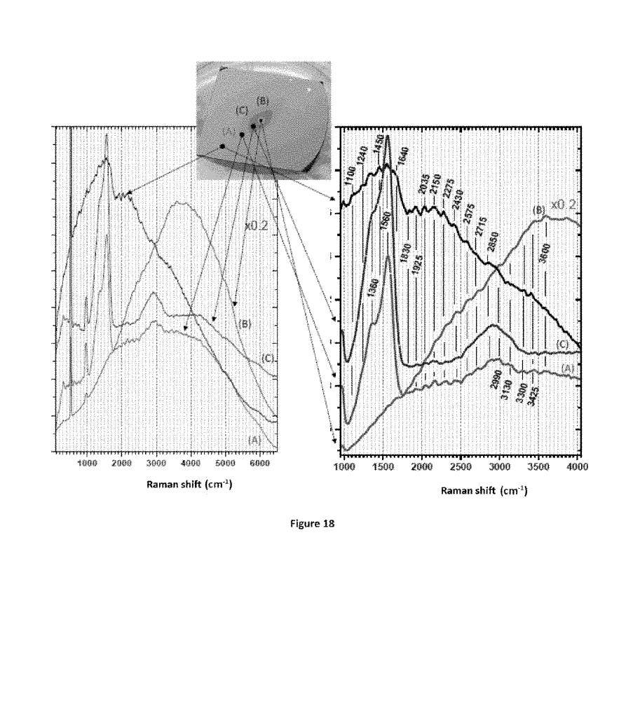

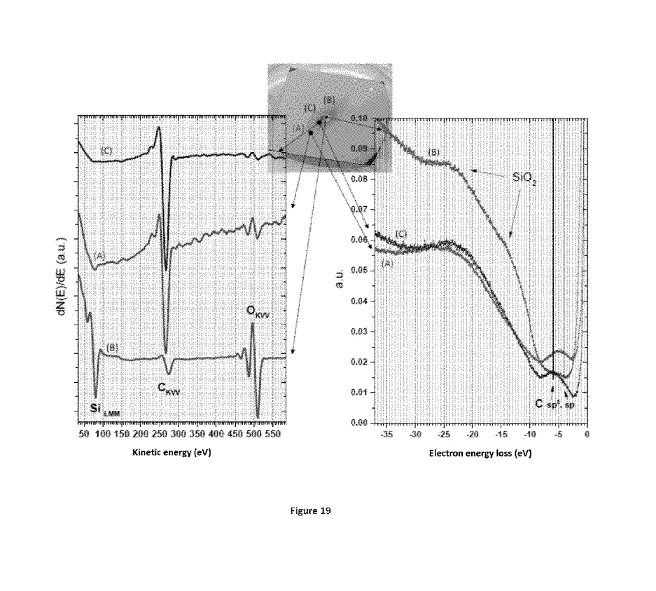

FIG. 18 shows the Raman spectra of the three layers obtained in the regions A, B and C shown in FIG. 17, and also the Raman spectrum corresponding to the deposition of agglomerates containing metastable carbyne/carbynoid chains not transformed using the beam of electrons (region D),

FIG. 19 shows the Auger and electron energy loss spectra corresponding to the three regions A, B and C shown in FIG. 17,

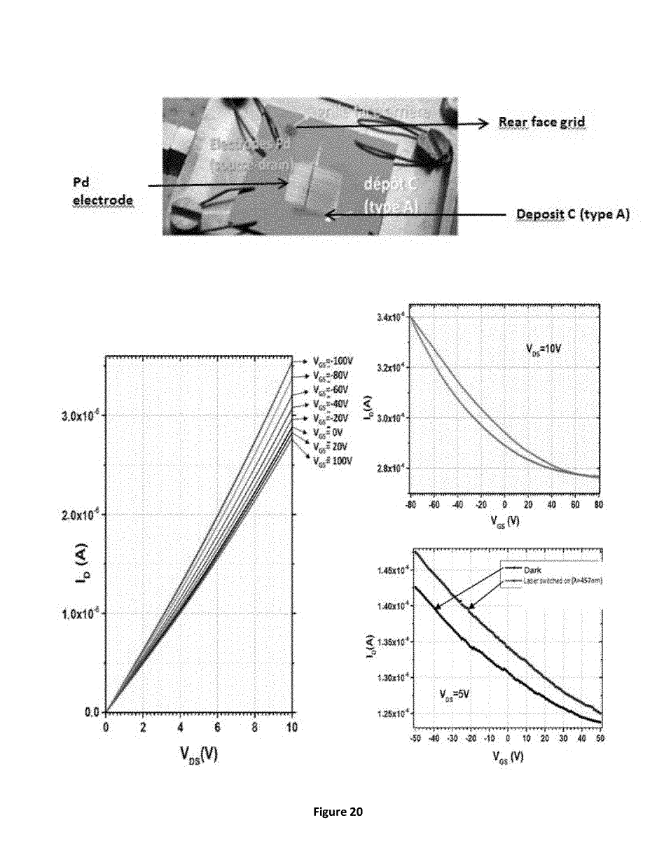

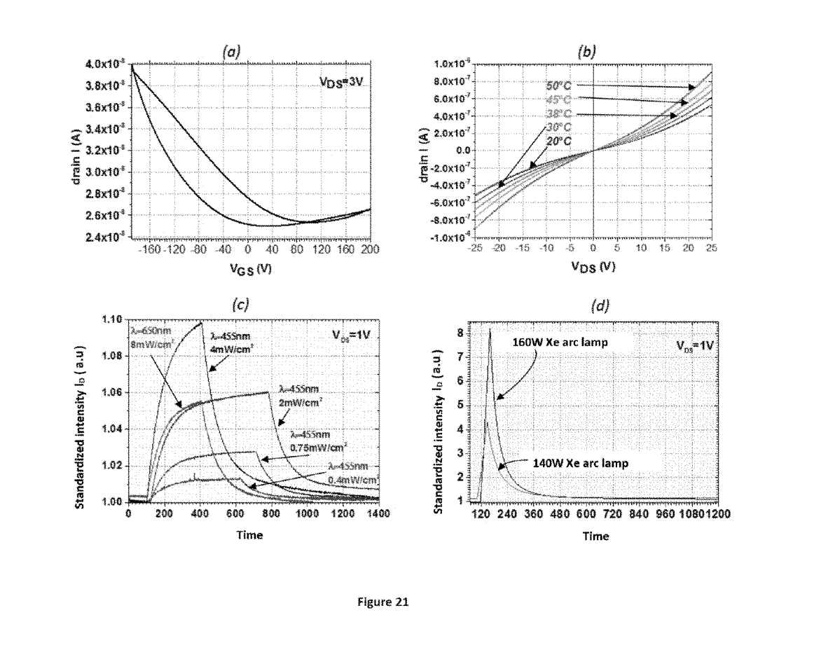

FIGS. 20 and 21 are illustrations of the use of the technique of localized deposition using a beam of electrons (type (A) of FIG. 17) to deposit a partially graphitized layer, in conforming manner, on Pd electrodes predeposited on the (degenerate) Si substrate covered with a layer of thermal silica (300 nm). This makes possible the simple manufacture of a device of the type of a field effect transistor having a rear face grid, the electrical characteristics of which are shown in FIG. 20. The semiconducting nature of the material deposited in localized manner using the beam of electrons is illustrated by the dependency of the temperature of the conductivity of the channel and by an effect of sustained photoconduction under exposure to the light, as shown in FIG. 21.

The current techniques which make it possible to respond to one or more of the criteria i) to vii) set out above are techniques of chemical vapor deposition (CVD) type which produce films of carbon (DLC, diamond, graphite/graphene, nanotubes) using vapor precursors in the form of hydrocarbon molecules which are optionally activated (radicals or ions). However, all these techniques currently require:

a. special substrates for the temperature (typically between 500° C. and 1000° C.) stability and/or comprising a catalyst,
b. some films (for example graphene) often have to be transferred subsequently onto the final substrate, and
c. if the growth is carried out at low temperature, subsequent stages of recrystallization (annealings at high temperatures which can exceed 1500° C., or high-energy laser annealings) can be employed but they also comprise major limitations in terms of compatibility of the substrate and often their the effectiveness is low/not very reproducible.

However, no CVD technique has to date made it possible to produce and isolate materials rich in carbon of carbyne or carbynoid type.

The invention resorts to a change in paradigm: instead of using hydrocarbon molecules/radicals for the CVD growth of various carbon films, use will be made of agglomerates, also known as clusters, of carbyne/carbynoid type.

This implies:

a. that the formation on the carbon film will be carried out by a condensation of the carbyne/carbynoid clusters. The surface properties (wettability/surface tension, presence of defects) will also have a strong effect on the formation of the carbon film,
b. that the carbon film can be “shaped” in situ, during its construction, as in conventional CVD, for example by the use of radical hydrogen, which is known to be highly reactive with regard to the different phases of carbon and in particular amorphous carbon (generally assumed of sp hybridization),
c. that the nature of the carbon film obtained can in addition be adjusted by controlling the nature of the carbyne/carbynoid clusters generated in the gas phase (length of the chains, type of ending of the chains), and
d. that the carbyne/carbynoid clusters can be caused to condense on a cooled substrate or placed in a cold region.

The process of the invention then becomes compatible with the use of supports made of almost the majority of known materials.

The film obtained will contain stabilized carbyne/carbynoid chains which can be subsequently “transformed”, in a controlled manner, into other types of materials having variable hybridization.

This is because the carbon-carbon triple bond is a “high energy” state for the carbon. The theoretical stability range of carbyne lies between that of graphite (the most stable phase) and diamond (see below).

This implies that:

i. under the effect of a slight disturbance of the condensed film (heating, illumination), the “high energy” carbon-carbon bonds will relax toward the most stable phase of graphite. Materials with variable compositions (in terms of carbon hybridization) and structures can thus be easily obtained. In this case, normal allotropies of carbon are concerned, which allotropies may exhibit highly advantageous properties for various applications,
ii. if such a film is subjected to a strong disturbance, for example to the exposure to a high energy laser beam (excimer or femtosecond lasers), the additional energy contributed may induce a swing toward the sp3 phase of the carbon and thus the formation of (nano)diamond.

Consequently, a first subject matter of the invention is a method for the synthesis of carbon agglomerates (clusters) (agglomerates containing carbon), these agglomerates containing metastable carbyne/carbynoid chains which will now be described with reference to FIGS. 1 and 2.

As is seen in FIGS. 1 to 4, the deposition of the carbon agglomerates containing carbynes/carbynoids according to the invention is carried out by CVD in a CVD chamber, denoted 12 in FIG. 1, 12′ in FIG. 2, 12″ in FIGS. 3 and 12′″ in FIG. 4, and takes place on the surface, denoted 11 in FIG. 1, 11′ in FIG. 2, 11″ in FIGS. 3 and 11′″ in FIG. 4, of a substrate, denoted 1 in FIG. 1, 1′ in FIG. 2, 1″ in FIGS. 3 and 1′″ in FIG. 4, placed from the viewpoint of a pipe for injection of carbon gas, denoted 9 in FIG. 1, 9′ in FIG. 2, 9″ in FIGS. 3 and 9′″ in FIG. 4.

The CVD chamber 12, 12′, 12″ and 12′″ comprises a heating resistor, denoted 7, 7′, 7″ and 7′″ in FIGS. 1 to 4 respectively, a transfer chamber, denoted 5 and 5′ respectively in FIGS. 1 and 2, and an appliance for placing under vacuum inside the CVD chamber. This appliance for placing under vacuum is denoted 4 and 4′ respectively in FIGS. 1 and 2 (not represented in FIGS. 3 and 4).

The systems represented in FIGS. 3 and 4 can also comprise a transfer chamber (not represented in FIGS. 3 and 4).

A thermocouple denoted 3 and 3′ respectively in FIGS. 1 and 2 (not represented in FIGS. 3 and 4) makes it possible to control the temperature of the substrate 1, 1′, 1″, 1′″.

The process of the synthesis of carbon agglomerates containing metastable carbynes/carbynoids of the invention comprises the formation of carbon vapor precursors containing metastable carbynes/carbynoids by decompositions of a carbon gas (CHₓ) at a temperature T such that 1500° C.<T≦3000° C. and the condensation of these vapor precursors on the surface 11, 11′, 11″, 11′″ of a substrate 1, 1′, 1″, 1′″, the temperature Ts of which is less than the temperature T.

For this, the CVD chamber 12, 12′, 12″, 12′″ is equipped with a means for heating the carbon gas which can either be a hot filament, denoted 6 in FIG. 1, 6′ in FIGS. 2 and 6″ in FIG. 3, or a device for heating by laser irradiation, denoted 10 in FIG. 4.

The carbon gas can be any gas containing carbon, such as methane (CH₄), acetylene (C₂H₂), ethylene (C₂H₄) or toluene or also benzene in the form of vapors.

This gas is decomposed locally under the effect of the high temperature obtained by the laser irradiation or by forced and confined passage through one or more metal filaments 6, 6′, 6″.

The metal filaments can be made of tungsten, tantalum, molybdenum or rhenium.

The vapor precursors of the carbon agglomerates containing metastable carbyne/carbynoid chains are subsequently condensed on the substrate 1, 1′, 1″, 1′″, placed in a colder region of the CVD chamber 12, 12′, 12″, 12′″.

When the heating is heating by laser irradiation, the laser used can be an infrared CO₂ laser or an excimer laser emitting UV radiation.

In a specific embodiment of the invention, a gas containing a doping element can also be injected into the CVD chamber.

This doping element can be nitrogen, boron, phosphorus or fluorine.

This gas containing the desired doping element can be introduced simultaneously with the carbon gas to be decomposed, as a mixture with the latter by the orifice 9, 9′, 9″, 9′″ or by a separate orifice, denoted 8, 8″, 8′″ in FIGS. 1, 3, 4.

The carbon gas can also be mixed with a carrier gas, such as helium.

Agglomerates of carbon compounds containing metastable carbyne/carbynoid chains deposited on the surface 11, 11′, 11″, 11′″ of the substrate 1, 1′, 1″, 1′″ will then be obtained, these agglomerates can be used to construct “tailor-made” innovative materials.

These agglomerates can make it possible to construct, directly on any substrate 1, 1′, 1″, 1′″, made of metal, of insulating material, of plastic, and the like, without constraints and in a controllable manner, novel and crystalline materials, such as, for example graphene or other materials of a graphitic structure, graphine, even diamond or nanodiamond.

This is because these carbon clusters containing metastable carbyne/carbynoid chains can be seen as molecular bricks which can be used to construct countless allotropic forms of carbon, many of which may exhibit unpublished and exceptional physicochemical properties.

This formation of compounds can be carried out continuously, at the same time as the formation of the clusters, directly on the substrate 1, 1′, 1″, 1′″ which will then be heated to the appropriate temperature to form the desired compound.

This heating can be carried out by irradiation of the flow of clusters being deposited on the surface 11, 11′, 11″, 11′″ of the substrate 1, 1′, 1″, 1′″ with UV radiation or with a laser or a source of photons or of electrons or of ions.

Optionally, a pressure can also be applied around the substrate 1, 1′, 1″, 1′″.

However, the agglomerates formed by the process of the invention can also be used to synthesize novel compounds after having been removed from the CVD chamber 12, 12′, 12″, 12′″ and placed in another chamber where, here again, the temperature conditions (obtained as above by irradiation with UV radiation or with a laser or a source of photons or of electrons or of ions) and pressure conditions appropriate for obtaining the desired compound will be applied.

In order to promote the formation of certain crystalline structures, the process of the invention makes it possible to choose the nature of the substrate 1, 1′, 1″, 1′″.

Thus, at least the surface 11, 11′, 11″, 11′″ of the substrate 1, 1′, 1″, 1′″ can be made of fused silica, in order to promote the formation of agglomerates and of layers of such agglomerates highly crystalline are for example graphene with inclusion of linear carbyne chains.

However, it will also be possible, before decomposing the carbon gas in the CVD chamber 12, 12′, 12″, 12′″, to treat the surface 11, 11′, 11″, 11′″ of the substrate 1, 1′, 1″, 1′″, for example by depositing thereon a layer of amorphous alumina in order to promote the formation of layers of graphene of high crystalline quality.

In this case, in order to obtain graphene, a temperature of 800° C. will be used as temperature of the substrate, and the filaments 6, 6′, 6″, preferably made of tungsten, will be heated to 2100° C., and a flow containing the carbon gas will be injected. For example, the carbon gas will be methane and the stream of gas injected will consist of 10% by volume of methane and of 90% by volume of hydrogen for a total pressure of 100 mbar.

The hydrogen is used, in this example where the deposition is carried out on alumina, to select the highly graphitic phase during the growth and to largely remove the other types of carbon.

It is the phase transformation which the alumina undergoes (crystallization) at this deposition temperature which is used to obtain the high crystalline quality of the graphene.

However, it will also be possible to control the nature of the agglomerates (clusters) deposited on the surface 11, 11′, 11″, 11′″ of the substrate 1, 1′, 1″, 1′″ by selective etching of certain phases of the carbon (sp, sp2 or sp3) by injecting, at the same time as the carbon gas to be decomposed, a flow of hydrogen. This flow of hydrogen generates, at temperatures obtained by the filaments 6, 6′, 6″ or by the laser 10, a flow of highly reactive (radical) hydrogen. This flow of highly reactive hydrogen (radical hydrogen) is used to control the nature of the carbon clusters containing carbyne chains, synthesized by the process of the invention, in order to modify the proportion of sp, sp2 or sp3 phase, in addition to the other control parameters.

For example, the hydrogen can be injected through the hot filaments 6, 6′, 6″ or the plasma created by the laser 10, as a mixture with the carbon gas, that is to say by the orifice 9, 9′, 9″, or separately from the latter (as represented in FIG. 2, where it is introduced by the separate orifice 8, 8″, 8′″).

Thus, another subject matter of the invention is a method for the synthesis of carbon compounds which comprises a stage A) of formation of a flow of agglomerates (clusters) or else of clusters (not in the flow form), containing metastable carbyne/carbynoid chains according to the process of the invention previously described and a stage B) of transformation of these clusters into the desired carbon material (the desired carbon compounds).

These carbon compounds can be allotropes of carbon, such as carbon nanomaterials (such as graphene, graphyne, graphdiyne, carbon nanotubes, carbon nanolaces), from the clusters formed by the process of the synthesis of carbon clusters (agglomerates) containing metastable carbyne/carbynoid chains of the invention.

There can also be other carbon compounds containing other elements than carbon.

In particular, it will be possible to synthesize films having a controlled structure, directly on the final substrate, conforming to the surface of this substrate, at low temperature and without constraints with regard to the nature of the substrate.

The films obtained can be doped and are compatible with large-scale production.

The processes of the invention can be used for the synthesis of molecules involving, for example, optionally cyclic polyene chains, novel or inaccessible to date, it being possible for these molecules to be used in particular in the pharmaceutical field.

The processes of the invention can also make possible the production of conforming coatings on various materials: it is sufficient to collect/condense, for example, the carbon clusters containing metastable carbyne/carbynoid chains on the object of interest and then to expose them to UV radiation in order to obtain a controlled transformation of these materials into a material composed solely of carbon. This material composed solely of carbon is a biocompatible material having exceptional mechanical and septic properties.

The processes of the invention can also be used to synthesize carbon in various forms, such as a graphite, graphene, (nano)diamond or linear carbyne chains having special properties.

It will also be possible to synthesize combinations of such materials in order to synthesize novel materials with exceptional properties with numerous potential applications, such as functional coating or reinforcement.

Furthermore, as the crystalline forms of carbon have exceptional properties (sp3—semiconductor diamond having a very large gap, sp2—semimetal graphene having very high mobility, sp—semimetal carbyne (cumulene) or semiconductor carbyne (polyyne) which is magnetic), it is possible, by virtue of the process of the invention, to combine these various materials “at will” in order to manufacture novel hybrid materials which make it possible to obtain novel semiconducting, conducting and/or insulating materials.

The processes of the invention also make possible the synthesis of the desired compounds directly on the substrate/support of interest without constraints of temperature, of composition or of need for transfer onto the desired substrate.

The processes of the invention also make it possible to obtain novel semiconducting materials, some of which have Dirac points, that is to say having a very high mobility of the carriers.

The materials obtained by the processes of the invention can be used for the manufacture of components of electronic devices, of sensors or of optoelectronic devices, including photovoltaic devices and flexible electronic devices.

However, the materials obtained by the processes of the invention can also be used for the storage of energy. This is because graphite can store one Li ion per 6 C atoms. A carbyne/carbynoid chain does not have this limitation. A hybrid having a high concentration of carbyne chains makes it possible to obtain a much higher capacity for insertion of the Li ions while retaining the exceptional properties of graphite in terms of cycling stability.

In order to make the invention better understood, a description will now be given, purely by way of illustration and without implied limitation, of several exemplary embodiments.

### EXAMPLE 1: SYNTHESIS OF CARBON CLUSTERS BY THE PROCESS OF THE INVENTION

CH₄ was decomposed by forced passage through the hot tungsten filaments at a temperature of 2100° C. in the CVD chamber 12 shown in FIG. 1.

The gases thus decomposed are entrained toward the surface 11 of the substrate 1 which is maintained at 500° C. by the heating means, noted 7, of the CVD chamber 12.

The CVD chamber 12 was under a pressure of 100 mbar.

The substrate 1 was made of glass.

A layer of carbon clusters containing metastable carbyne/carbynoid chains was obtained by condensation on the glass substrate 1 of the gases resulting from the decomposition of the CH₄.

The Raman spectrum of this layer is represented in FIG. 5.

The difficulty in obtaining pure samples of carbynes/carbynoids means that reference Raman spectra are difficult to find in the literature. Furthermore, theoretical calculations demonstrate that the bonds of polyyne type and the cumulenes have similar Raman spectra. It is generally accepted that the sp bonds of carbon exhibit, depending on the length of the chain of carbon atoms, Raman bands in the region of 1750 cm⁻¹ to more than 3000 cm⁻¹. It is also accepted to use a semi-empirical formula which relates the position of the characteristic Raman bands to the number of the pairs of carbon atoms with bonds of sp (triple bond or double bond) type. This formula, proposed by Kastner et al. (J. Macromolecules, 1995, 28, 344-353; L. Kavan and J. Kastner, Carbyne and Carbynoids, 1999, pages 342-356), is:

Freq (in cm⁻¹)=1750+3980/N

where N=number of pairs of carbon atoms with bonds of sp type.

Consequently, the Raman spectrum obtained for the layer obtained in this example and shown in FIG. 5 confirms the presence of carbynes/carbynoids in this layer.

### EXAMPLE 2

The procedure was carried out as in example 1 and in the same CVD chamber 12. However, the substrate was a substrate comprising an alumina (Al₂O₃) layer (30 nm) deposited on a substrate of silicon oxidized at the surface SiO₂ (300 nm)/Si maintained at a temperature of 450° C. The decomposition of CH₄ gas was carried out at 2250° C.

The Raman spectrum of the condensed layer obtained is represented in FIG. 6. The presence will be noted of numerous bands attributable to the carbynes/carbynoids, with even very long chains formed (bands at approximately 1780 cm⁻¹), present in the layer deposited, which furthermore also contains a graphitic material (sp² carbon), the characteristic D and G bands of which are strong. The crystalline nature of the material is also confirmed by the presence of the second order (2x), indeed even third order bands.

### EXAMPLE 3: SYNTHESIS OF GRAPHENE BY THE PROCESS FOR THE SYNTHESIS OF CARBON MATERIALS ACCORDING TO THE INVENTION

### a) Synthesis of Carbon Clusters Containing Metastable Carbyne Chains.

The procedure was carried out as in example 1, except that, in addition, hydrogen was also introduced by the orifice 8 of the CVD chamber represented in FIG. 1 and that the substrate was an Al₂O₃/SiO₂/Si substrate.

### b) Synthesis of Graphene.

As the CH₄ decomposes and as the gas resulting from this decomposition condenses, on the substrate 1 maintained at a temperature of 800° C., a graphene layer was formed.

The graphene layer thus obtained was analyzed by Raman spectroscopy.

The Raman spectrum obtained is represented in FIG. 7.

It will be noted, from this FIG. 7, that, in comparison with the preceding example, the material obtained in the present example is predominantly graphene, as is suggested by the presence of the strong and thin G and respectively 2D bands. It is noted, from the ×10 magnification of this figure, that L1, L2 and L3 bands characteristic of the linear chains of sp carbon are still present, although weaker. This is thus a hybrid material consisting of islets of graphene connected by carbyne bridges.

### EXAMPLE 4: FORMATION OF A GRAPHITE LAYER BY THE PROCESS ACCORDING TO THE INVENTION

The procedure was carried out as in example 1, that is to say by decomposition of CH₄ by forced passage through hot tungsten filaments at a temperature of 2100° C. and condensation of the gases thus decomposed on a glass substrate.

However, in this example, the substrate 1 was maintained at a temperature of 50° C.

The Raman spectrum of the layer of agglomerates containing metastable carbyne/carbynoid chains thus obtained is represented in FIG. 8.

It is seen, in this figure, that the layer obtained contains predominantly carbynes/carbynoids of variable lengths, as is demonstrated by the presence of numerous characteristic bands between 1750 cm⁻¹ and 3000 cm⁻¹. The material contains a very low proportion of graphitic carbon (D and G bands at 1350 and 1600 cm⁻¹), probably resulting from the crosslinking reaction of the carbyne chains.

The substrate coated with this layer was subsequently subjected to exposure to the light beam of a (Xe) arc lamp delivering 300 cd (3000 lumens) focused on approximately 5 cm² and which also emits (>10%) of the light in the range of the UV radiation and IR radiation (˜10%).

The Raman spectrum of the layer thus transformed is represented in FIG. 8.

It is seen, from FIG. 8, that, under the effect of the light flux, crosslinking reactions of the carbyne chains were initiated and that the material changed toward a material having a high proportion of graphitic carbon, as is indicated by the intensification of the characteristic G and D bands.

### EXAMPLE 5: FORMATION OF A GRAPHENE/CARBYNE LAYER BY THE PROCESS ACCORDING TO THE INVENTION

The procedure was carried out as in example 1, that is to say by decomposition of CH₄ by forced passage through hot filaments at a temperature of 2100° C. and condensation of the gases thus decomposed on a substrate made of Si covered with a 100-nm silica layer.

However, in this example, the substrate 1 was maintained at ambient temperature.

The deposition was carried out in an ultrahigh vacuum chamber on which the source of generation of the carbyne/carbynoid clusters described in FIG. 3 was fitted. The pressure P1 at the inlet of the orifice 9′ was a few tens of mbar. The pressure at the outlet (ultrahigh vacuum chamber where the substrate is placed) was 4×10⁻⁷ mbar. The estimated flow rate of the gas was 0.05 sccm. Under these conditions, the number of carbon atoms injected should make it possible (assuming the use of 100% of the carbon originating from the injected CH₄) to deposit the equivalent of a carbon monolayer over the surface of the sample (25×25 mm) every 30 minutes approximately.

The Auger spectrum of the layer of agglomerates containing metastable carbyne/carbynoid chains thus obtained is represented in FIG. 11 with in situ and real-time monitoring over a period of time of 700 minutes. The possible material thickness to be probed by this technique, under the experimental conditions used (beams of incident electrons which are very low-angled with respect to the surface of the sample), is limited to approximately 1-2 nm.

There is seen, from FIG. 11, the formation of a deposit of carbon which reaches, toward the end of the deposition (very strong attenuation of the Si and O signals corresponding to the substrate), a thickness of the order of a nanometer.

The residual pressure in the ultrahigh vacuum chamber was monitored, over the entire duration of the deposition, by mass spectroscopy, as shown in FIGS. 9 and 10.

As may be seen, the flow of methane injected into the source of generation of the carbyne/carbynoid clusters described in FIG. 3 undergoes a dissociation of more than 99%, the detectable resulting products being predominantly recombined hydrogen (mass spectrum in correlation with the total pressure in the chamber). The carbon resulting from this dissociation forms clusters of carbynes/carbynoids of high mass, outside the range of detection of the spectrometer which is being used.

It is possible to use this flow of clusters of carbynes/carbynoids in order to condense them on a substrate, as in the preceding examples. FIG. 14 shows the Raman spectrum of the layer resulting from this condensation on a substrate of Si covered with silica (100 nm), the deposition being carried out at ambient temperature. The presence of the carbynes/carbynoids is noted. In comparison with the preceding example (and FIG. 8), it is noted that the lower thickness of material deposited does not result in crosslinking reactions, no signal of graphitic type (G and D bands) being present in the spectrum.

Even more, during the deposition, it is possible to use a focused source of photons, electrons or indeed ions in order to bring about a local transformation of the flow of the clusters or carbynes/carbynoids during deposition, in order to manufacture, in a localized manner, the desired carbon material.

An example in which a beam of electrons (1 to 5 keV) is used is shown in FIG. 12, in which, at the right-hand side, the fluorescence spot of the focused beam (diameter approximately 1.5 mm) is noted, whereas, at the left-hand side, the fluorescence spot of the beam of electrons in the course of scanning a surface (diamond) of approximately 0.7 cm² is observed.

In the region scanned by the beam of electrons during the deposition using the stream of the clusters of carbynes/carbynoids, the localized deposition, at ambient temperature, of a material having the same morphology as the region of scanning of the beam of electrons is noted, as illustrated in FIG. 13.

The Raman analysis shown in FIG. 15 (mean over 30 random points within the diamond) of the irradiated region shows the formation at ambient temperature of a crystalline and graphitic film with inclusions of carbyne chains. The transformation is located solely at the region of writing with the beam of electrons. This is illustrated by FIG. 14, which shows the Raman spectrum (mean over 30 random points in a circle of approximately 1 cm around and outside the diamond) of the deposition outside the region of writing. The spectrum shows the presence of the clusters of carbynes/carbynoids which have not been transformed.

This is of extreme importance for the microelectronics industry as it will make possible the construction (according to the type of carbyne/carbynoid clusters, presence or absence of dopants, temperature, irradiation dose and energy of the electrons), at will, in a localized manner (with the accuracy of the beams of electrons in current electron beam (e-beam) devices, which achieve an accuracy of a nanometer), and even at ambient temperature, on all types of supports, of different types of carbon materials with the desired properties. Consequently, it is possible in practice “to write” a whole electronic circuit, with extreme flexibility of its design and of its functionalities, in a vacuum system, which can replace a white room, over any support, at ambient temperature. Even more, it is possible to control, in situ and in real time and at each writing point, the nature of the material formed. The example is provided by the analyses shown in FIG. 11 and by the analyses shown in FIG. 16, which represents the energy loss spectrum of the electrons (beam used for the writing of FIG. 12), showing the formation of a layer containing carbon of sp and sp2 type.

### EXAMPLE 6: FORMATION AND TRANSFORMATION OF A GRAPHENE/CARBYNE LAYER BY THE PROCESS ACCORDING TO THE INVENTION

The procedure was carried out as in example 5, that is to say by decomposition of CH₄ by forced passage through the hot filaments at a temperature of 2250° C. and condensation of the gases thus decomposed on a substrate made of Si covered with a 100-nm silica layer and maintained at ambient temperature.

The deposition was carried out in an ultrahigh vacuum chamber on which the source of generation of the carbyne/carbynoid clusters described in FIG. 3 was fitted. The pressure P1 at the inlet of the orifice 9′ was 100 mbar. The pressure at the outlet (ultrahigh vacuum chamber where the substrate is placed) was 5×10⁻⁶ mbar. The flow rate of the gas was 1 sccm.

During the deposition, a source of electrons was used to bring about a local transformation of the flow of the clusters of carbynes/carbynoids in the course of deposition, in order to manufacture, in localized manner, the desired carbon material.

In a first step, the beam of electrons (2.5 keV, 10 μA) is used as illustrated in FIG. 17A (in which the fluorescence spot of the focused beam is noted at the right-hand side) in order to scan a surface (diamond) of approximately 0.7 cm², as in example 5, for 30 min.

In a second step, the source of generation of the carbyne/carbynoid clusters which is described in FIG. 3 is halted. A flow of molecular oxygen (0.1 sccm, pressure in the chamber 5×10⁻⁷ mbar) is injected into the chamber by the orifice 8′. In this case, the beam of electrons (2.5 keV, 10 μA) is used as illustrated in FIG. 17B in focused mode (diameter of approximately 1.5 mm) at the center of the region of the deposition (scanning) carried out previously.

In a third step, the injection of the flow of oxygen is halted. Under ultrahigh vacuum this time (pressure in the chamber 10⁻¹⁰ mbar), the beam of electrons (2.5 keV, 10 μA) is used as illustrated in FIG. 17C (in which, at the right-hand side, the fluorescence spot of the focused beam is noted) to scan a surface (diamond) of approximately 0.3 cm², still centered with respect to the first region of the deposition carried out previously.

FIG. 17 shows the photographs of the surface of the samples at the end of these treatments and removed from the deposition chamber. The presence of three deposition regions (contrast difference) with different apparent characteristics, the morphology of which perfectly matches the three types of writing/scanning by the beam of electrons, is noted.

FIG. 18 shows the Raman spectra corresponding to three regions A, B and C of FIG. 17 (corresponding to the three types of deposition carried out). The Raman spectrum corresponding to the deposition of agglomerates containing metastable carbyne/carbynoid chains not transformed using the beam of electrons (outside the regions of writing) and which is similar to the results obtained in example 5 is also shown.

In the region A corresponding to the region scanned by the beam of electrons while the carbyne/carbynoid clusters were in the course of deposition (operation of the source of generation of the carbyne/carbynoid clusters which is described in FIG. 3), the formation is noted of a material identical to that obtained in example 5 (FIG. 8) and which contains islets of graphenes connected by carbyne bridges.

In the region B, corresponding to the region exposed to the focused beam of electrons and in the presence of a flow of oxygen, the virtual disappearance of the graphene/carbyne bands is noted, a sign of the local destruction of the material previously deposited. It is important to note that this destruction is highly localized solely in the region irradiated by the beam of electrons as, as is shown by the spectra, over the remainder of the surface (region A and unscanned region), the carbon deposit was not affected.

The spectrum of the region C, corresponding to the region scanned by the beam of electrons, under ultrahigh vacuum, in superposition over the deposition region A, shows that it is possible to continue the transformation (in this case graphitization) of the layer deposited previously in the region scanned by the beam of electrons while the carbyne/carbynoid clusters were in the course of deposition (operation of the source of generation of the carbyne/carbynoid clusters which is described in FIG. 3). This deposit still contained a high fraction of carbyne/carbynoid clusters. As is demonstrated by Raman spectra, the bands characteristic of the carbyne/carbynoid clusters are greatly attenuated in the region C in favor of an intensification of the G, D and 2D bands characteristic of graphene/graphite.

These three examples are a very good illustration of the use of the local transformation, in situ, at ambient temperature, of agglomerates containing metastable carbyne/carbynoid chains using a beam of electrons according to the three basic processes in the microelectronics industry: region (A) localized deposition of a material (in this case having controllable and modifiable properties) using the metastable carbyne/carbynoid chains generated by the device shown in FIG. 3; region (B) local destruction/removal of this material using the beam of electrons in the presence of oxygen (pressure 10⁻⁶ mbar) without affecting the material in the neighboring region not exposed to the beam of electrons; and region (C) transformation of a portion of the material deposited in region (A) under the effect of exposure to a higher dose of the beam of electrons.

As in example 5, the beam of electrons can be used (by carrying out Auger electron spectroscopy or electron energy loss spectroscopy), in situ and in real time, to obtain information on the (local) nature of the material in the course of deposition or of transformation.

FIG. 19 shows the Auger and electron energy loss spectra corresponding to the three processes used in the three corresponding regions, A, B and C in FIG. 17. These spectra, in addition to the Raman analysis, confirm the local destruction of the layer deposited (region B) and also the local transformation (accentuated graphitization) of this layer (region C).

### EXAMPLE 7: FORMATION AND TRANSFORMATION OF A LAYER OF GRAPHENES/CARBYNES BY THE PROCESS ACCORDING TO THE INVENTION AND MANUFACTURE OF A DEVICE OF FIELD EFFECT (PHOTO)TRANSISTOR TYPE

The procedure was carried out as in example 6, that is to say by decomposition of CH₄ by forced passage through the hot filaments at a temperature of 2250° C. and condensation of the gases thus decomposed on a substrate maintained at ambient temperature. The deposition was carried out in an ultrahigh vacuum chamber on which the source of generation of the carbyne/carbynoid clusters which is described in FIG. 3 was fitted. The pressure P1 at the inlet of the orifice 9′ was 100 mbar. The pressure at the outlet (ultrahigh vacuum chamber where the substrate is placed) was 5×10⁻⁶ mbar. The flow rate of the gas was 1 sccm. During the deposition, a source of electrons (2.5 keV, 10 μA) was used to scan a surface of approximately 0.7 cm² in order to bring about the local transformation of the flow of the clusters of carbynes/carbynoids in the course of deposition, in order to manufacture, in localized manner and in conforming manner, the desired carbon material.

The substrate used was made of (degenerate) Si covered with a layer of thermal silica (300 nm). A set of Pd electrodes, which may be observed in FIG. 20 (at the top) was deposited beforehand (shadow masking technique) on its surface. The carbon layer deposited in conforming manner on this set of electrodes was used as conduction channel in a device of the field effect transistor type having a rear face grid, the electrical characteristics of which are shown in FIGS. 20 and 21.

The semiconducting nature of the material deposited in localized manner using the beam of electrons is also illustrated in FIG. 21 by the dependency of the temperature of the conductivity of the channel and by an effect of sustained photoconduction under exposure to light (commercial diodes at 454 nm, 650 nm and with a broad-spectrum Xe arc projection lamp). It should be noted that this effect of sustained photoconduction is rarely (and only very recently: Nature Nanotechnology, 8, 826-830 (2013); Nano Lett., 2011, 11 (11), pp. 4682-4687) obtained at ambient temperature.

1. A process for the synthesis of carbon agglomerates containing metastable carbyne/carbynoid chains, wherein the method comprises the following stages:
a) forming of carbon vapor precursors containing in carbyne/carbynoid chains by decomposition of a carbon gas chosen from CH₄, C₂H₂, C₂H₄, gaseous toluene and benzene in the form of vapors at a temperature T such that 1500° C.<T≦3000° C.,
b) condensing of the carbon vapor precursors obtained in stage a) on the surface of a substrate, the temperature Ts of which is less than the temperature T.

2. The process as claimed in claim 1, wherein stage a) is a stage of forced passage of the carbon gas through at least one metal filament made of a material chosen from tungsten, tantalum, molybdenum and rhenium, heated to the temperature T in a chamber.

3. The process as claimed in claim 1, wherein stage a) is a stage of heating by laser irradiation.

4. The process as claimed in claim 1 wherein in addition, a carrier and/or diluent gas is injected at the same time as the carbon gas by a separate orifice or by the same injection orifice as the carbon gas.

5. The process as claimed in claim 1 comprises, in addition, before stage a), a stage a1) of pretreatment of the surface of the substrate.

6. The process as claimed in claim 5, wherein the pretreatment stage a1) is a stage of deposition on the surface of the substrate of a layer made of amorphous alumina or a stage of functionalization of the surface of the substrate.

7. The process as claimed in claim 1 at least the surface of the substrate is made of fused silica.

8. A process for the synthesis of carbon materials, wherein the method comprises a stage A) of synthesis of carbon agglomerates comprising metastable carbyne/carbynoid chains by the process as claimed in claim 1, followed by a stage B) of transformation of the agglomerates obtained in stage A) into the desired carbon material, this stage B) being carried out in a separate chamber.

9. The process as claimed in claim 8, wherein stage B) is carried out by irradiation of the agglomerates obtained in stage A), as they are deposited on the surface of the substrate, with a source of photons, of electrons or of ions, whereby a localized transformation of the agglomerates into the desired carbon material is obtained.

10. The process as claimed in claim 8, wherein stage B) is carried out by heating the agglomerates containing carbyne/carbynoid chains obtained in stage b) of stage A) to the temperature necessary in order to obtain the transformation of these agglomerates into the desired material.

11. The process as claimed in claim 8, wherein stage B) is a stage of irradiation by UV radiation of the agglomerates containing carbyne/carbynoid chains obtained in stage b) of stage A).

12. The process as claimed in claim 8, wherein stage a) of stage A) additionally comprises the injection, into the chamber, of a gas containing a doping element or the injection of hydrogen, at the same time as the carbon gas, by the same orifice as the carbon gas or by a separate orifice.

13. A method of synthesizing chemical molecules containing polyene and/or polycyclic chains and/or for the formation of conforming coatings composed solely of carbon and/or graphenes, graphites, nanodiamonds or fullerenes comprising using the carbon agglomerates containing metastable carbyne/carbynoid chains obtained by the process as claimed in claim 1 for the synthesis of chemical molecules containing polyene and/or polycyclic chains and/or for the formation of conforming coatings composed solely of carbon and/or for the synthesis of graphenes, graphites, nanodiamonds or fullerenes.

14. Method of using the carbon agglomerates containing metastable carbyne/carbynoid chains obtained by the process as claimed in claim 1 as semiconducting material.

15. Method of using the carbon agglomerates containing metastable carbyne/carbynoid chains obtained by the process as claimed in claim 1 for the manufacture of components of electronic devices.

16. Method of using the carbon agglomerates containing metastable carbyne/carbynoid chains obtained by the process as claimed in claim 1 for the storage of energy.

17. The process as claimed in claim 3, wherein the laser is an infrared CO₂ laser or an excimer (UV) laser, of the carbon gas in a chamber.

18. The process as claimed in claim 12, wherein the gas contains nitrogen, boron, phosphorus, fluorine, or a mixture thereof.
